(19) United States
(12) Patent Application Publication
(10) Pub. No.: US 2008/0049512 A1
(43) Pub. Date: Feb. 28, 2008

(54) Nonvolatile memory device and method of programming the same

(76) Inventors: Konrad Seidel, Dresden (DE); Uwe Augustin, Dresden (DE); Gert Koebernick, Dresden (DE); Soren Irmer, Radebeul (DE); Daniel-Andre Loehr, Dresden (DE); Volker Zipprich-Rasch, Dresden (DE); Mirko Reissmann, Ottendorf-Okrilla (DE)

Correspondence Address: EDELL, SHAPIRO & FINNAN, LLC, 1901 RESEARCH BLVD., SUITE 400, ROCKVILLE, MD, 20850, US

(21) Appl. No.: 11/508,336

(22) Filed: Aug. 23, 2006

(51) Int. Cl. G11C 11/34; G11C 16/06; G11C 16/04

(52) U.S. Cl. 365/185.22; 365/185.24

(57) ABSTRACT

A method for conducting programming and erasure of charge-trapped memory devices includes: conducting at least one program/erase cycle of a charge-trapped memory device on the basis of a given threshold voltage of the charge-trapped memory device as a reference point; determining a wear-level of the erasing procedure; shifting the reference point according to a result of the determination of the wear-level; conducting one or more program/erase cycle on the basis of the shifted threshold; and conducting read and verify operations on the basis of the shifted threshold.

### FIELD OF THE INVENTION

The invention relates to nonvolatile memory devices and to a method of programming nonvolatile memory devices.

### BACKGROUND

Nonvolatile memory devices have been known for some decades. Their main characteristic is that data stored therein is not lost when the device is turned off. In principle, two different groups of nonvolatile memory devices can be distinguished: so called “charge-trapping” devices on the one hand and floating gate devices on the other hand. The present invention focuses especially on the first of the mentioned groups.

In charge-trapping memory devices, the electric charge is stored within a nitride trap, for example. A nitride read-only memory (NROM) is a special charge-trapping memory device. An NROM cell is basically an n-channel Metal Oxide Semiconductor Field-Effect Transistor (MOSFET) with the gate oxide being replaced by an oxide-nitride-oxide structure (ONO). Such cells allow the permanent storage of charges. Due to the localized charge storage of NROMs and the symmetrical structure of the transistor, it is possible to store two bits of charge per transistor.

In order to program an NROM device, charges have to be injected into the nitride layer. There is at present one main method used for programming of an NROM device, which is called hot-carrier injection (HCl) or in particular channel hot electron (CHE) injection. The hot electrons are produced by applying a strong lateral electric field between the source and the drain of the transistor. By that field, electrons are accelerated on their way through the channel from the source to the drain region. Due to collisions between those electrons, some of them can gain sufficient energy to pass the barrier constituted by the bottom oxide layer of the ONO structure if an appropriate positive voltage is applied to the gate of the transistor. This effect leads to the trapping of those hot electrons in the nitride layer.

Due to the fact that the trapping layer is non-conductive or has a low conductivity and the comparable low lateral component of the electric field in the charge trapping layer, the electrons are trapped individually and remain localized within that layer. This is in contrast to the above mentioned floating gate devices which have their charges stored in a conductive layer which results in a lateral movability of the charges. A negative effect of that movability is the potential draining of the whole charge of the storage layer due to only a point defect in the floating gate insulator. As to the charge trapping devices, point defects in the bottom insulation layer as mentioned do not lead to total charge draining but only to a loss of charges immediately above the point defect.

Erasure of the NROM preferably takes place by injecting hot holes (HH) into the charge trapping layer. The hot holes are generated by applying an electric field between the drain region and the gate of the transistor and tunnel through the bottom oxide layer into the charge trapping layer where they recombine with the trapped electrons. In this way, the stored charge is erased.

It has turned out that the erase as well as the program performance change after repeated cycling (programming and erasing) of an NROM cell. As to erasing of the NROM, during cycling, the erasure-steplevel rises, a fact which is commonly known under the name “ERS degradation”. On the other hand, cells are getting more sensitive for programming on precycled areas, i.e., with increasing cycle count. Thus, the stability of the performance of a NROM cell will be reduced with an increasing number of program-erase-cycles.

Another problem in connection with the endurance of the NROM is the moving of the self-conduction threshold V_{tsc} on precycled areas. By programming all cells below the selfconduction threshold, it can be avoided that the cell gets into the state of self-conduction. Self-conduction induces leakages during sensing among all cells of affected bitlines of a NROM array. This leads to wrong sensing results and failing operation of all E-sectors which are members of a certain slice. Self-conduction can be induced by the following effects: a) defects (“Kux-Bits”); b) wrong settings of the erasure settings; and c) very large cell-length variations which leads to a wide erasure distribution.

The influence of precycling on the selfconduction threshold of an NROM can be seen from FIG. 1. This figure shows a diagram in which the hot hole current of a memory cell IcellHH of an investigated Victim ES (Victim erasable sector) is plotted over the leak source voltage V_{tLL} for different cycling numbers. As can be seen from that figure, the self conduction threshold which is the value of the voltage at which the decrease of the hot hole current stops, is shifted by about 300 mV (increase from 1.5V to 1.8V) after 50,000 cycles. This phenomenon can be explained using the model of a NROM cell which states a shortened channel length after the stress caused by repeated programming and erasing. The insertion of holes into the charge trapping layer (nitride layer) leads to a shorter effective channel which is responsible for the increasing self-conduction threshold V_{tsc}.

However, increase of the selfconduction threshold may have a negative impact on the sensing accuracy and on bitline disturb in shared bitlines of a plurality of transistors.

### SUMMARY

The invention provides a method for conducting programming and erasure of a charge-trapping memory device, the method includes: a) conducting at least one program/erase cycle of a charge-trapped memory device on the basis of a given threshold Vₜₕ of the charge-trapped memory device as a reference point; b) determining a wear-level of the erasing procedure; c) shifting the reference point according to a result of the determination of step b); d) conducting one or more program/erase cycles on the basis of the shifted threshold; and e) conduct read and verify operations on the basis of the shifted threshold. Steps b) to d) can be carried out repeatedly for the whole of the lifetime of the memory device.

In the following, the shifting of the reference point will sometimes also be referred to as “adapting the cycle margin.”

Preferably, the charge-trapped memory device comprises one or more NROM cells. Especially, the charge-trapped memory device can be an array of NROM cells in suitable cell architecture.

The threshold Vₜₕ may be a voltage applied between a gate and a source of the charge-trapped memory device during erasure.

In accordance with one embodiment of the invention, the determining step comprises counting the program/erase cycles already carried out. This can be achieved for example by incorporating a counter into the charge-trapping memory device. According to that embodiment, the shifting step is carried out after a predetermined cycle number which can be set depending on the kind of memory device used. The distance between the cycle numbers can be constant or varying. A shifting step may for example be carried out every 100 cycles or every 500 cycles or even every 1000 cycles. On the other hand, the first shifting step may be initiated after the first 100 cycles, whereas the next shifting step is carried out after the next 500 cycles, the next after 1,000 cycles and another one after 10,000 cycles.

The determining step comprises determining the shift of the threshold Vₜₕ on the basis of a steplevel of erasure of a previous cycle.

The amount of shifting of step c) is preferably derived from a look-up table correlating different wear-levels with respective amounts of shifting. The look-up table can be conveniently stored in a special region of the charge-trapping memory device.

The present invention is also directed to a charge-trapped memory device, comprising at least one memory cell, the memory cell comprising:

a substrate in which a source region and a drain region are provided separated from each other by a channel region;

a bottom oxide layer overlying the channel region;

a charge-trapping layer above the bottom oxide layer;

a top oxide layer above the charge-trapping layer; and

a gate provided on the top oxide layer;

wherein the memory device further includes a determiner for a wear-level of the erasure procedure and a shifter for shifting a reference point of an erase procedure of the memory cell. The mentioned memory device is especially adapted to carry out the method of the present invention.

Furthermore the memory device of the invention may comprise a storage section having stored therein a look-up table correlating different wear-levels with respective amounts of shifting.

In a preferred embodiment of the invention, the memory cell of the charge-trapping memory device is an NROM.

The charge-trapping memory device has a an intrinsic threshold Vₜₕ, which is for example the threshold value of a voltage applied over the gate and the source for erasing procedures. The threshold Vₜₕ determines a voltage to be applied between a gate and a source of the charge-trapped memory device during erasure.

As it has already been indicated in connection with the method given above, the determiner may be a counter for counting program/erase cycles already carried out.

Alternatively, the determiner comprises a write only memory section for memorizing an erasure step level and a comparator for comparing the last erasure step level with a predetermined threshold level for the erasure step level (see FIG. 8).

The above and still further features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The invention is explained in more detail below with reference to the figures which show exemplary embodiments only and are not intended to limit the scope of the claims, where:

FIG. 1 shows a diagram in which the hot hole current of a memory cell IcellHH of an investigated Victim ES (Victim . . . ) is plotted over the leak source voltage V_{tLL} for different cycling numbers;

FIG. 2 is a sectional view of an exemplary charge-trapping memory cell;

FIGS. 3 and 4 are diagrams showing the effect of cycle margin adaptation for the V_{PPD}max characteristics for programming and erasing, respectively;

FIG. 5 is a graph showing the bitline disturb versus threshold voltage.

FIG. 6 is another graph showing the retention after cycling for adaptive cycle margin NROM structures and for fixed cycle margin NROM structures;

FIG. 7 shows the retention behavior of different NROM structures with constant cycle margin of 1000 mV and with adaptive cycle margin according to the present invention; and

FIG. 8 shows a block diagram of an embodiment of the charge-trapped memory device.

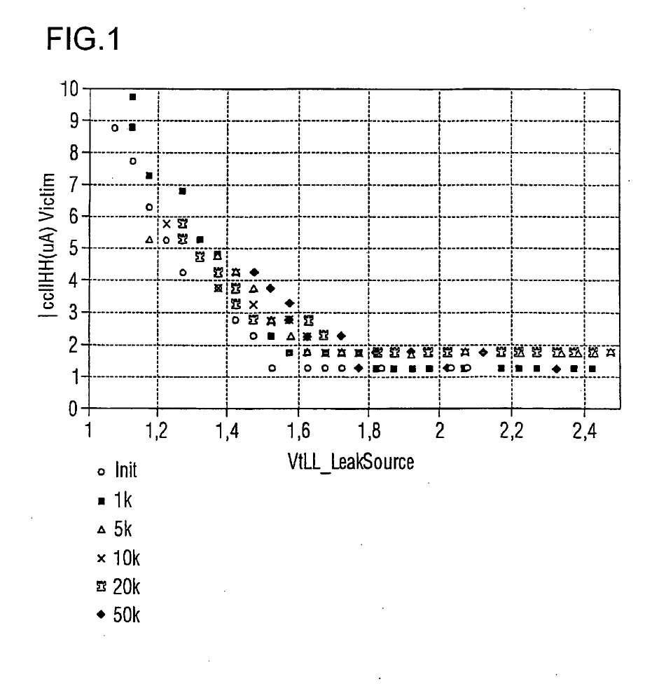

### DETAILED DESCRIPTION

In the following detailed description, reference is made to accompanying drawings which form a part hereof and in which is illustrated by way of illustration, specific embodiments in which the invention may be practiced. In this regard, directional terminology such as “above”, “below”, “between”, “upper”, “top”, “bottom”, “front”, “back”, “leading”, “trailing”, etc. is used with reference to the orientation of the Figures being described. Because components of the embodiments of the present invention can be positioned in a number of different orientations, the directional terminology is used for purposes of illustration and is no way limiting. It is to be understood that other embodiments may be utilized and structural or logical changes will be made without departing from the scope of the present invention. The following detailed description, therefore, is not to be taken in a limiting sense, and the scope of the present invention is defined by the appended claims.

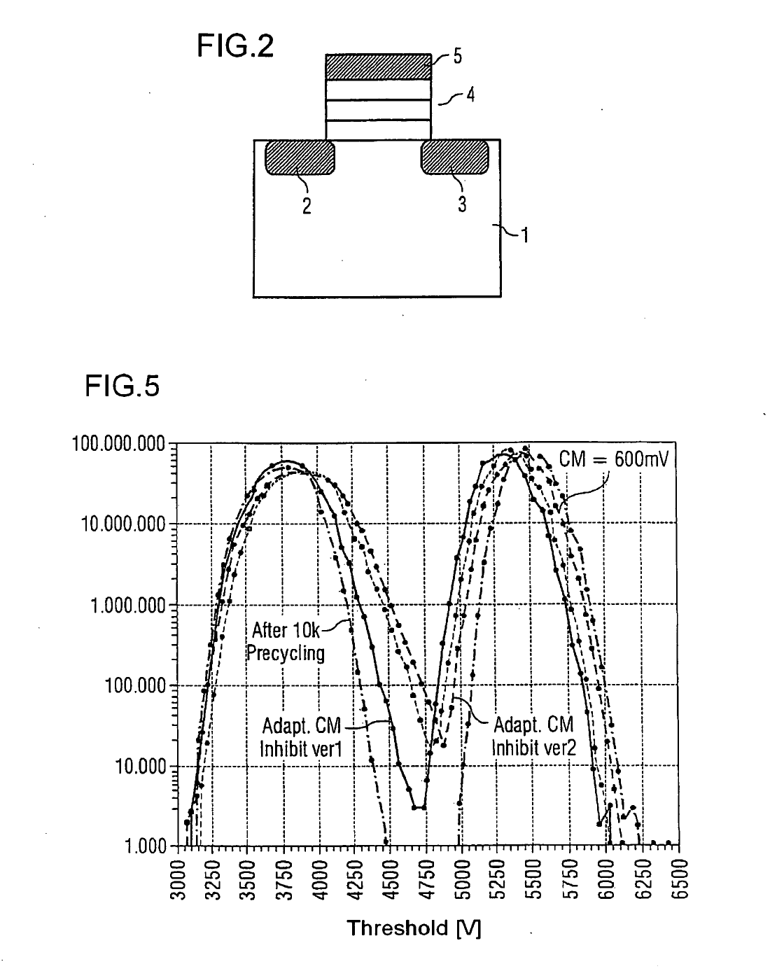

In the drawings, FIG. 2 shows the principal set up of a charge-trapping memory cell in form of an NROM. The cell is comprised of a substrate 1, in the present case a p-type substrate, having embedded therein a source region 2 and laterally separated from a drain region 3. The area of the substrate 1 connecting the source region 2 and the drain region 3 constitutes a channel enabling electron drift in response to a voltage being applied over the source region and the drain region. Above the channel, there is disposed an oxide-nitride-oxide stack 4 which enables permanent and localized storing of electrons in the nitride layer, i.e., trap layer. A gate 5 overlies the upper one of the two oxide layers (top oxide layer). The NROM cell thus constitutes a transistor.

Due to the localized storage and the symmetrical setup of the transistor, it is possible to store two bits of charge per transistor. As this is known by the person skilled in the art, the programming using the channel hot electron (CHE) method, a first voltage is applied between the source and drain regions and a second Voltage or gate voltage V_{CCR} is applied between the source region and the gate. The effect is the acceleration of electrons along the channel and the trapping of hot electrons having enough energy to pass the bottom oxide layer within the nitride layer of the ONO 4.

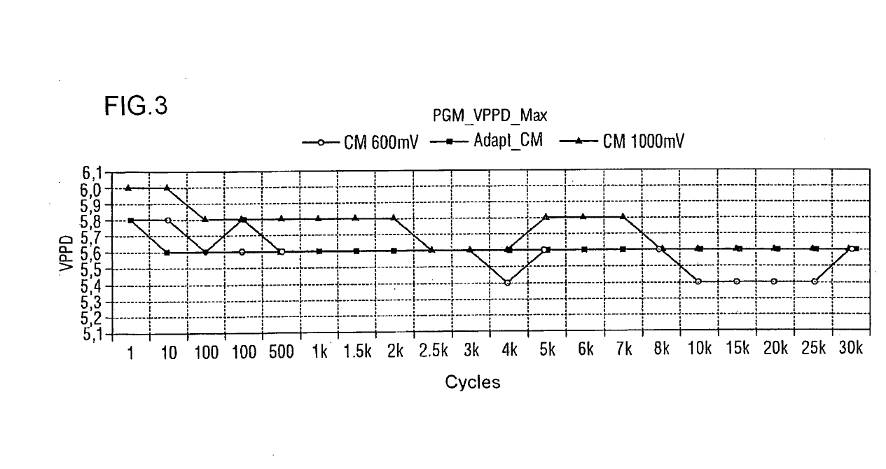

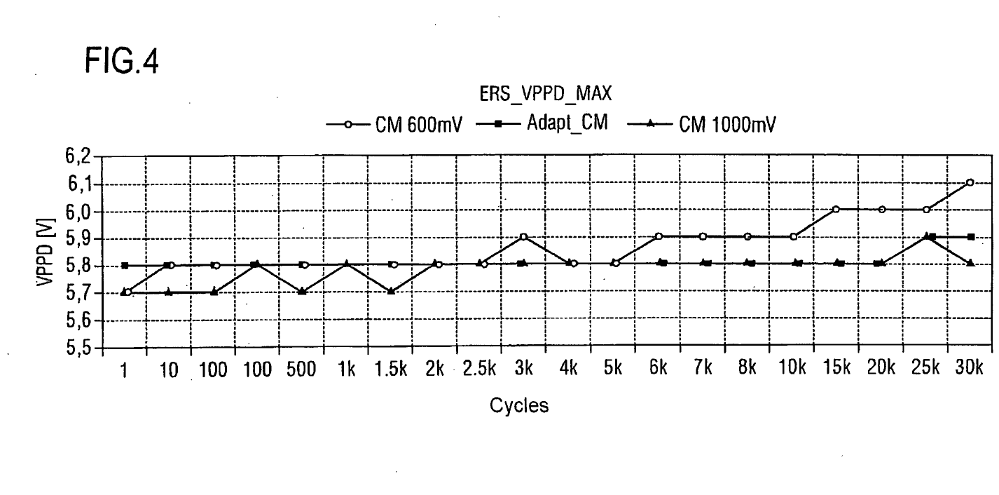

FIGS. 3 and 4 show measurement values plotted in a diagram the x-axis of which gives the number of program/erase cycles and the y-axis representing the maximum drain voltage needed for erasing, V_{PPD} max for the programming and the erasing case, respectively. The experiments resulting to the above diagrams have been carried out using an EF11 NROM structure manufactured by Qimonda. Due to there being an array of NROMs, for adapting the cycle margin, it could be chosen to either change a test register of all V_{CCR} gate voltages or the V_{CCR}-reference voltages. In the experiments described below, changing of the V_{CCR} was chosen. For the cycling (program/erase cycles), normal cycling flow was used with the following changes made: increasing the cycle margin by 100 mV after 100, 500, 1000 and 10000 cycles. Increasing the cycle margin means reducing the V_{CCR}-reference voltage by the value mentioned.

The reason for choosing increasing cycle number differences, after which an adaptation of the cycle margins (shifting of the reference point) was carried out, is that the applicants were aware of the fact that the degradation of erasing performance is stronger at the begin of life and nearly saturates versus the end of life of an NROM. In practice, when using a cycle counter for determining the wear-level of the erase performance, the appropriate cycle counts for each special device should be characterized and stored in advance.

An endurance experiment was carried out on the mentioned NROM structure including 30000 program/erase cycles. In the diagrams of FIGS. 3 and 4, the white line gives the values of an NROM structure the cycle margin of which was increased step by step from 600 mV to 1000 mV after the above mentioned cycle counts. For comparison, an identical NROM structure was tested with a constant cycle margin of 600 mV in the above figures. The corresponding graphs are plotted in black lines. Also for comparison, respective third NROM structures underwent the same testing with the mere difference that the cycle margin was kept constant on a high value of 1000 mV. The performance of the third test NROM structures is plotted in the grey line.

One E-sector, erasable sector which means the smallest unit to be erased in one step, was cycled for each of the above given cycle margins. The behavior of the programming steplevel V_{PPD}max can be derived from the graphs of FIG. 3 and the behavior of the erasing steplevel V_{PPD}max can be seen from FIG. 4.

It can be seen from FIG. 3 that the high cycle margin test NROM structure provides the worst performance especially at the beginning. This is due to the fact that the programmability is getting weaker with increased cycle margins. Best results at end-of-life conditions (here after 30000 cycles) are obtained by the low constant cycle margin when considering only the program performance. As a compromise, a stable program-performance over cycling can be achieved when using the adaptive cycle margin according to the present invention.

FIG. 4 shows the V_{PPD}max characteristic of the erasure performance. Here, the worst performance is obtained when using the low constant cycle margin, especially at higher cycle counts. The best performance is delivered by the high cycle margin which in contrary showed the worst results on the programming tests. Again, the adaptive cycle margin according to the present invention appears to be stable over cycling.

For investigation of the bitline disturb of a NROM array, a so called “Killer-Pattern” and a Victim erase were used. The disturb was done with 50,000 Killers using either fixed cycle margin at 600 mV or adaptive cycle margin which changed from 600 mV to 1000 mV as mentioned above. To reduce the disturb on the programmed side, the erase Vinhibit was adapted in parallel to the cycle margin scheme.

In the figure, version 1 constitutes a switch from 3.1V to 3.5V after 500 cycles and version 2 constitutes a switch from 3.1V to 3.5V after 500 cycles and to 4.3V after 10,000 cycles. The results show a clear difference between both approaches, CM 600 mV versus adaptive cycle margin of inhibit ver.1. This is due to the fact that for the 600 mV cycle margin the erasure steplevel went up during cycling. With a shunt-transistor of the array being operated at constant V_{CCR}, a floating bitline of the structure sees a higher voltage difference to a bitline driven by the increased erase V_{PPD}. This increased voltage difference leads to a stronger soft-programming of the erased cells. The adaptive cycle margin does not face this soft-programming since the erase V_{PPD} remains constant and hence no significant voltage drop between the bitlines is forced. As seen in the figure, the inhibit version 2 is overcompensated. The voltage drop on the programmed side is a superposition of disturb and retention after cycling.

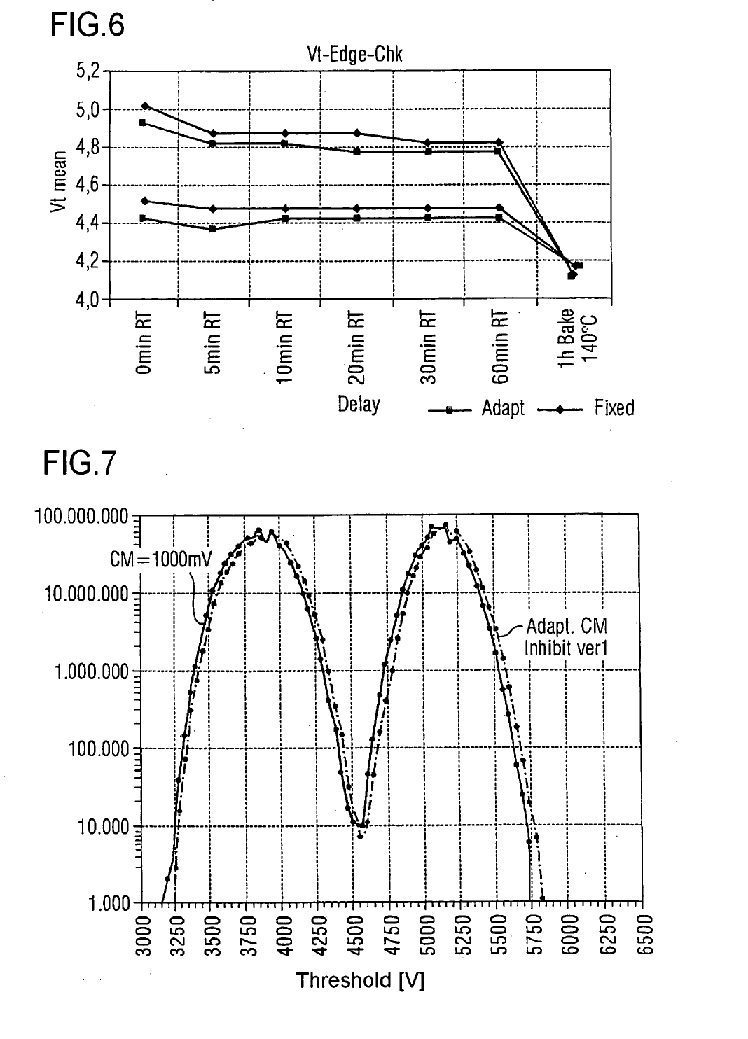

From FIG. 6, the results of a retention experiment carried out on an adaptive cycle margin NROM structure as described above and according to a NROM structure having the cycle margin fixed at 600 mV can be seen. The structures had undergone 10,000 cycles of precycling with the killer pattern previously described. The measured threshold voltage Vₜₕ for different times after cycling at room temperature until 60 minutes was plotted on the y-axis. Furthermore, the measured threshold voltage was also plotted after the structures had undergone baking for one hour at 140° C.

As can be seen from FIG. 6, the adaptive cycle margin NROM structures seem to have the same retention behavior like the fixed cycle margin NROM structures. Obviously, when adapting the cycle margin to the cell parameter, equal stress conditions can be achieved, even for high cycle margins which are similar to higher program margins, i.e., more program stress.

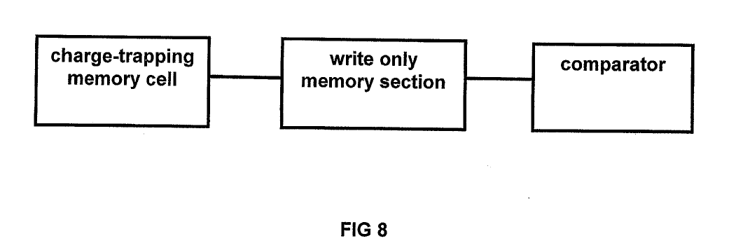

The comparison between the retention behaviors of the adaptive cycle margin NROM and the NROM with cycle margin fixed at 1000 mV is shown in FIG. 7. From that figure, it can be concluded that there is hardly any difference between both precycling approaches.

As a result of the previous investigation, it is proposed according to the present invention to increase the cycle margin which means the shifting of a reference point of a NROM memory device at certain stages within the erase/program cycle. Accordingly, the cycle margins are adapted to the intrinsic NROM properties during use.

The adaptation can be best realized by use of a look-up table in which there are stored shift values for the reference point for different cycling numbers or for different last erasure step levels.

Change of the cycle margin is a good measure to elude the upcoming leakage threshold on the one side and to keep the erasure and program performances stable over lifetime on the other side.

During cycling, the erasure steplevel increases, a phenomenon known as erasure degradation. When increasing the cycle margin, the cells are getting easier to erase. In combination with the erase degradation a stable erase performance over lifetime can be achieved.

Also the program performance can be stabilized, as already mentioned above. During the course of cycling, the cells are getting easier programmed but an increased cycle margin slows down the program performance. This again in combination with the adaptive cycle margin leads to a constant program performance over lifetime.

Therefore, the step levels will not increase drastically, which means that the array stress and the probability of failure are low.

According to one aspect of the present invention, this is achieved by storing a cycle counter, for example on each E-sector of the NROM structure. Based on the counter value, a stored algorithm can be carried out which derives the appropriate adaptation of the cycle margin using a stored look-up table. The latter has to be defined during characterization for after process technology change, i.e., POR change.

According to a second aspect, the cycle margin is changed as soon as the erase steplevel has reached a certain threshold. The last cycle margin is stored in a fuse-concept, e.g., write once read only memory, on the one time programmable read only memory (OTP) for each erasure.

With the present invention, danger of self-conduction can be avoided. Furthermore, a reduced bitline disturb can be achieved as has been shown above. Finally, NROM memory devices with adapted cycle margin also show a better endurance behavior than corresponding NROM devices having a fixed cycle margin.

While the invention has been described in detail and with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

1. A method for conducting programming and erasure of charge-trapped memory devices, the method comprising:
a) conducting at least one program/erase cycle of a charge-trapped memory device based on a given threshold voltage of the charge-trapped memory device;
b) determining a wear-level of the program/erase cycle by memorizing an erasure step level and comparing a last erasure step level to a predetermined threshold level for the erasure step level;
c) shifting the threshold voltage according to the wear-level;
d) conducting one or more program/erase cycles based on the shifted threshold voltage; and
e) conducting read and verify operations based on the shifted threshold voltage.

2. The method according to claim 1, wherein the charge-trapped memory device comprises one or more nitride read-only memory (NROM) cells.

3. The method according to claim 1, wherein the threshold voltage is a voltage applied between a gate and a source of the charge-trapped memory device during an erase cycle.

4. The method according to claim 1, wherein b), c), and d) are conducted repeatedly.

5. The method according to claim 1, wherein b) comprises determining the shift of the threshold voltage via a steplevel of erasure of a previous cycle.

6. The method according to claim 1, wherein c) further comprises deriving a shift amount from a look-up table correlating different wear-levels with respective amounts of shifting.

7-10. (canceled)

11. A charge-trapped memory device, comprising at least one memory cell, the memory cell comprising:
a substrate including a source region, a drain region, and a channel region separating the drain region and the source region;
a bottom oxide layer overlying the channel region;
a charge-trapping layer overlying the bottom oxide layer;
a top oxide layer overlying the charge-trapping layer;
a gate disposed on the top oxide layer;
a write only memory section for memorizing an erasure step level;
a comparator configured to determine a wear-level of an erase cycle of the memory cell by comparing a last erasure step level to a predetermined threshold level for the ereasure step level; and
means for shifting a reference point of an erase cycle of the memory cell.

12. The charge-trapped memory device according to claim 11, further comprising a storage section including a look-up table correlating different wear-levels with respective amounts of shifting.

13. The charge-trapped memory device according to claim 11, wherein the memory cell is a nitride read-only memory (NROM).

14-15. (canceled)

16. The charge-trapped memory device according to claim 11, wherein the charge-trapping memory device has an intrinsic threshold voltage.

17. The charge-trapped memory device according to claim 16, wherein the threshold voltage is a voltage applied between the gate and the source region of the charge-trapped memory device during an erase cycle.
